(19) United States
(12) Patent Application Publication
(10) Pub. No.: US 2016/0087132 A1
(43) Pub. Date: Mar. 24, 2016

(54) Dynamic PV Module And Method Of Manufacturing

(71) Applicant: Hamad Musabeh Ahmed Saif Alteneiji, Sharjah (AE)

(72) Inventor: Hamad Musabeh Ahmed Saif Alteneiji, Sharjah (AE)

(21) Appl. No.: 14/491,759

(22) Filed: Sep. 19, 2014

(51) Int. Cl. H01L 31/05; H01L 31/18; G01R 31/40; H02S 40/36; H02S 40/34

(52) U.S. Cl. CPC H01L 31/0504; H02S 40/36; H02S 40/34; H02S 50/00; H01L 31/18; H01L 31/1876

(57) ABSTRACT

There is provided a dynamic photovoltaic module omprising the photovoltaic module comprising a number of cell stacks connected in serial therebetween, each cell stack among said cell stacks comprising a number of photovoltaic cells connected in parallel therebetween. In a preferred embodiment, each cell stack comprises a same number of photovoltaic cells having a same cell voltage and cell current equal to the quotient of the module current and the cell current and the number of cell stacks in the module being equal to the quotient of the module voltage and the cell voltage. The proposed dynamic PV module is adapted to mitigate the problem of mismatch effects hence improving the performance of PV modules caused by conditions such as partial and full shading, soiling, non-uniform illuminations, solar concentration and clouds, inside-module defects like broken cells or connectors. There is also provided a method of manufacturing a dynamic PV module.

### FIELD OF THE INVENTION

The present invention relates to generally to photovoltaic modules, and more particularly to a dynamic photovoltaic module and method of manufacturing.

### BACKGROUND OF THE INVENTION

A PV module consists of a number of interconnected solar cells encapsulated lasting, stable unit. A bulk silicon PV module consists of multiple individual solar cells connected, nearly always in series, to increase the power and voltage above that from a single solar cell (see FIG. 1).

While the voltage from the PV module is determined by the number of solar cells, the current from the module depends primarily on the size of the solar cells and also on their efficiency.

If all the solar cells in a module have identical electrical characteristics, and they all experience the same insulation and temperature, then all the cells will be operating at exactly the same current and voltage. In this case, the IV curve of the PV module has the same shape as that of the individual cells, except that the voltage and current are increased. The I-V curve of a PV array is a scale-up of the I-V curve of a single cell (see FIG. 2).

Mismatch losses are a serious problem in PV modules and arrays. Mismatch losses are caused by the interconnection of solar cells or modules which do not have identical properties or which experience different conditions from one another like illumination and temperature.

As most PV modules are series-connected, series mismatches are the most common type of mismatch encountered. Overall, in a series connected configuration with current mismatch, severe power reductions are experienced if the poor cell produces less current than the maximum power current of the good cells and also if the combination is operated at short circuit or low voltages, the high power dissipation in the poor cell can cause irreversible damage to the module.

One famous type of current mismatch in a PV module is shading. Shading is a problem in PV modules since shading just one cell in the module can reduce the power output to zero. The high power of good cells will dissipate in the shaded cell that can cause irreversible damage to the module due to high temperature. The output of a cell declines when shaded by a tree branch, building or module dust. The output declines proportionally to the amount of shading since cells in a module are all connected in series. Therefore, shading a single cell causes the current in the string of cells to fall to the level of the shaded cell. The case is also reflected on all PV modules that are connected in series in the same string.

In conventional systems equipped with string inverters where the MPP-Tracking is performed on a string basis, some modules operate below their maximum power point due to differences in module tolerances and lighting conditions.

At a scale of PV array, the PV CURVE of the entire array exists as the series sum of the modules and the parallel sum of the strings. A shadow moving over the surface of several modules over time has the effect of constantly changing the PV curve from one smooth peak to more of a mountain range. As the peaks of the PV curve in the inverter change from the shade, the electronics that track the maximum power point can become confused or lost, causing the inverter to choose to operate for long periods of time well outside the optimal output range. This can cause significant loss of power output and eventually annual energy yield. Several categories of losses that can reduce PV array output are illustrated in FIG. 3.

Many modern panels, however, come equipped with devices called bypass diodes which minimize the effects of partially shaded PV panel by essentially enabling electricity to ‘flow around’ the shaded cell or cells. This bypass solution will protect the panel from forming Hot-Spot, however the power of good cells covered by same bypass diode will be lost and voltage contribution will be deducted from the overall system voltage that might force solar inverter to switch off in case the received voltage is less than start up voltage.

### SUMMARY OF THE INVENTION

In order to overcome the above mentioned drawbacks, there is provided a dynamic PV module and method of manufacturing.

The proposed dynamic PV module design is adapted to overcome and mitigate the limitation and problems associated with traditional designs for PV modules with respect to current mismatch, enabling higher performance and variety of application while using the same material and production facility.

The proposed dynamic PV module design is adapted to mitigate the problem of mismatch effects as well as improving the performance of solar PV modules. The proposed dynamic PV module concept is applicable for all PV technologies like crystalline and thin film.

The term “dynamic” means that PV module will be able to adapt itself under different applied conditions such as partial and full shading, soiling, non-uniform illuminations, solar concentration and clouds passing in the sky as well as mitigating the effect of inside-module defects like broken cell or connector. This new module should give more power under standard test conditions and much higher output under real conditions, using the same solar cell type.

The basic idea of the design concept is to replace the PV module traditional solar cells series string connection design, in order to overcome and mitigate its limitations and associated mismatch problems, by innovative module design that has new solar cells connection architecture which defines and describes the size of solar cells and their connection configuration. The proposed dynamic PV module is naturally self adaptive against changing illumination conditions like partial and full shading caused by object, leaf, clouds and soiling and/or increased light from reflection material. It will be able to absorb the current mismatch impact, resulted from difference of amount of sun light received by a single cell or deviation in cells efficiencies in the same string, and distribute that pressure within the relevant cells to pass module current and avoid any internal power dissipation. In this case by-passing protection is only used at extreme conditions. With respect to the same module area and cell efficiency, the new dynamic PV module should generate higher power under STC, standard test conditions, due to certain design factors that reduce series resistance power loss and increase exposed cells area. At real operation conditions, it will generate much higher energy (20%-30%) and that can be doubled in case module is coupled with fixed sheet reflector in angular position, without sun tracker, as a unique advantage of the dynamic PV module. The dynamic PV module design can be optimized as per intended locations and applications.

The technology is based on a new module architecture using internal solar cells structure. A new design of solar cell is introduced. The solar cell, of any size, will be cut into several equal sizes, sub-cells, that are connected in parallel as stack. Balancing bus-bars will be introduced to maintain same voltage cross all sub-cells in stack. All cell stacks will be installed and connected in series in straight line. Although each sub-cell will act as normal solar cell but in case any of them receive more or less light, all sub-cells in the same stack will agree to have the same voltage that fulfill the requirement to pass the string current through them. String current will be distributed among them as per the I-V curve of individual sub-cell capability, the higher I-V curve the more current percentage will pass through it. That means fair distribution of string current between them. The impact of current mismatch between both the module current and cell-stack current will result in a change in stack-voltage (through its I-V curve) that let stack current match module current and end current mismatch. In simple words, It is a series parallel cells interconnection to create more paths for module current to pass through in case of any blocking at any point to avoid any mismatch, power dissipation and hot spot formation. So, in general it can be said that, in ideal case, if any object blocks any part of the module, the result should be limited to power reduction of blocked part contribution only from the overall module output power.

The dynamic PV module design concept can utilize the material and production lines used to produce traditional PV module in order to produce dynamic PV module that has the advantages of producing higher energy yield and be naturally self adaptive to changing illumination conditions like shading (hard and soft, partly and fully), soiling, dirt and leaf, in addition to mitigate the effect of manufacturing defect like mixed lower grade cells, broken cell or connector as well as helping in accelerating melting of snow coverage and increasing output from any additional light reflection or diffused light.

The dynamic PV module concept can be applied to most of PV technologies. A dynamic PV module can be produced with the same production lines and material and can be tested and used as a normal PV module with advantages of additional dynamicity and performance.

The advantages of the new concept are numerous. In production, the same material can be used to produce a dynamic PV module. The same production line can be used with slight change in stringer fingers to handle smaller cells. However, an additional stage may be required to add balancing bus-bars. The additional cost and time for production will be minor. The proposed dynamic PV module can be optimized at the design stage for different electrical specifications like higher voltage and lower current or vice versa with respect to same module power, in addition to increasing the dynamic property of PV module. It can be applied for different PV technologies like crystalline and thin film. It is adapted to mitigate and hide the defects and differences in PV module like difference in cells efficiencies (nothing identical) or cell grades and broken cell and connectors, and to mitigate and eliminate the formation of a hot spot.

In application, the proposed dynamic PV module would produce more power (around 10%) at STC and more energy at real operation conditions (20%-30%). It can adapt itself under different applied conditions like partial and full shading, soiling, non-uniform illuminations, solar concentration and clouds passing in the sky. It can accelerate melting of snow coverage due the fact that dynamic PV module can produce energy if any slight light reached any exposed part of the of the module and create electrical and heat energies. It allows better light penetration and distribution when the concept is applied to semi transparent glass to glass PV module for green-houses due to the use of smaller arranged solar cells strips.

As a first aspect of the invention, there is provided a dynamic photovoltaic module having a module voltage and a module current, the photovoltaic module comprising a number of cell stacks connected in serial therebetween, each cell stack among the cell stacks comprising a number of photovoltaic cells connected in parallel therebetween, where each cell stack among the cell stacks has a cell stack voltage and a cell stack current and each photovoltaic cell among the photovoltaic cells has a cell voltage and a cell current such that the total voltage inside the module is equal to the module voltage and the total current inside the module is equal to the module current. According to an embodiment, the number of cells in each stack can vary and the cell voltage and cell current can vary such that the total voltage and total current inside the module equal to the module voltage and module current respectively.

Preferably, each cell stack among the cell stacks comprises a same number of photovoltaic cells having a same cell voltage and cell current, the number of photovoltaic cells being equal to the quotient of the module current and the cell current and the number of cell stacks in the module being equal to the quotient of the module voltage and the cell voltage. Preferably, the photovoltaic module comprises at least one bypass diode connected between the cell stacks in order to bypass the current through cell stacks experiencing a mismatch effect.

Preferably, the at least one bypass diode is connected such that one bypass diode is connected in parallel between each two adjacent cell stacks or a group of adjacent sell stacks.

Preferably, the photovoltaic module further comprises at least one redundant bypass diode connected in parallel to the at least one bypass diode.

Preferably, each photovoltaic cell has a cell width and a cell length, and wherein the number of photovoltaic cells in a cell stack is equal to the quotient of the cell length and the cell width.

Preferably, the ratio of the cell length and the cell width is an integer number equal or above 2. Preferably, the ratio of the cell length and the cell width is between 2 and 20. More preferably, the ratio of the cell length and the cell width is greater than 20.

The module voltage and the module current can be adjusted values taking into consideration the effect of environmental temperature and light radiance on the module.

Preferably, the photovoltaic module further comprises bus-bars adapted to enable the parallel connection between the photovoltaic cells within a same cell stack.

Preferably, the photovoltaic module further comprises string lines (or ribbons) adapted to enable the serial connection between the different cell stacks.

As another aspect of the invention, there is provided A method of manufacturing a dynamic photovoltaic module having a module voltage and a module current adapted to reduce loss of energy caused by current mismatch inside the module, the method comprising forming a number of cell stacks connected in serial therebetween, each cell stack among the cell stacks comprising a number of photovoltaic cells connected in parallel therebetween, where each cell stack among the cell stacks has a cell stack voltage and a cell stack current and each photovoltaic cell among the photovoltaic cells has a cell voltage and a cell current such that the total voltage inside the module is equal to the module voltage and the total current inside the module is equal to the module current.

Preferably, each cell stack among the cell stacks comprises a same number of photovoltaic cells having a same cell voltage and cell current, the number of photovoltaic cells being equal to the quotient of the module current and the cell current and the number of cell stacks in the module being equal to the quotient of the module voltage and the cell voltage.

Preferably, the method further comprises connecting at least one bypass diode between the cell stacks in order to bypass the current through cell stacks experiencing a mismatch effect.

Preferably, at least one bypass diode is connected such that one bypass diode is connected in parallel between each two adjacent cell stacks or a group of adjacent cell stacks.

Preferably, the photovoltaic module further comprises at least one redundant bypass diode connected in parallel to the at least one bypass diode.

Preferably, the method further comprises providing original PV cells having an original cell current, an original cell voltage, an original cell length and an original cell width; and cutting the original PV cells for producing the PV cells used for forming the cell stacks, the PV cells having a cell length and a cell width.

Preferably, the original PV cells are cut using laser. However, these can be cut using any other suitable means.

Preferably, the cell voltage is the same as the original cell voltage and the cell current is equal to the quotient of the original cell current and the number of PV cells per stack.

Preferably, the cell length is the same as the original cell length and wherein the cell width is equal to the quotient of the original cell width and the number of PV cells per stack.

Preferably, the number of PV cells per stack is equal or above 2. More preferably, the number of PV cells per stack is between 2 and 20. More preferably, the number of PV cells per stack is above 20 (cost considerations to be taken into account as the increase of the number of cells per stack increases the energy efficiency by reducing the loss of energy caused by current mismatch however can have an effect of increasing costs of manufacturing).

Preferably, the number of PV cells is determined based on energy efficiency and cost considerations, where an increase in the number of PV cells per stack increases the cost of manufacturing the PV module from one side and increases from an other side the energy efficiency of the PV module by reducing the loss of energy caused by current mismatch inside the module.

Preferably, the module voltage and the module current are adjusted values taking into consideration the effect of environmental temperature and light radiance on the module.

Preferably, the parallel connection between the PV cells within each cell stack is conducted using bus-bars.

Preferably, the serial connection between the different cell stacks is conducted using string lines (or ribbons).

As a further aspect of the invention, there is provided a dynamic PV system comprising at least two dynamic PV modules according to any embodiment of this invention connected therebteween in parallel or in serial.

### BRIEF DESCRIPTION OF THE DRAWINGS

FIG. 1 illustrates a traditional PV module having 36 PV cells connected in serial;

FIG. 2 illustrates the I-V curve of a PV array which is a scale-up of the I-V curve of a single cell;

FIG. 3 illustrates various categories of losses that can reduce the PV array output;

FIG. 4 illustrates a traditional PV module having 6 PV cells connected in serial;

FIG. 5 illustrates a dynamic PV module having 3 stacks of 2 PV cells each in accordance with an embodiment of the present invention;

FIG. 6 illustrates a dynamic PV module having 6 stacks of 2 PV cells each in accordance with an embodiment of the present invention;

FIG. 7 illustrates a dynamic PV module having 6 stacks of 3 PV cells each in accordance with an embodiment of the present invention;

FIG. 8 illustrates a dynamic PV module having 6 stacks of 4 PV cells each in accordance with an embodiment of the present invention;

FIG. 9 illustrates a dynamic PV module having 6 stacks of 5 PV cells each in accordance with an embodiment of the present invention;

FIG. 10 illustrates a dynamic PV module having 6 stacks of 6 PV cells each in accordance with an embodiment of the present invention;

FIG. 11 illustrates that all stack configurations have the same overall cell surface area size and same electrical parameters;

FIG. 12 illustrates the current, voltage and power in a dynamic PV module having 3 stacks of 4 cells each in accordance with an embodiment of the present invention;

FIG. 13 a), b) and c) illustrates the I-V Curves of the different configurations of a PV module in accordance with an embodiment of the present invention;

FIG. 14 illustrates a dynamic PV module having 30 stacks of 4 cells each in accordance with an embodiment of the present invention;

FIG. 15 illustrates a dynamic PV module having 2 sub modules of 30 stacks of 4 cells each where the sub modules are connected in parallel each in accordance with an embodiment of the present invention;

FIG. 16 illustrates a dynamic PV module having a module of 60 stacks of 6 cells each in accordance with an embodiment of the present invention;

FIG. 17 illustrates a dynamic PV module having a module of 64 stacks of 8 cells each in accordance with an embodiment of the present invention;

FIG. 18 illustrates a dynamic PV module having a module of 72 stacks of 6 cells each in accordance with an embodiment of the present invention;

FIG. 19 illustrates a dynamic PV module having a module of 100 stacks of 10 cells each in accordance with an embodiment of the present invention;

FIG. 20 illustrates a dynamic PV module having a module of 6 stacks of 6 cells each with by-pass diodes connected in parallel between adjacent stacks in accordance with an embodiment of the present invention;

FIG. 21 illustrates a dynamic PV module having a module of 70 stacks of 6 cells each with adjusted current and voltage to compensate for a decrease in the module current due to environmental factors in accordance with an embodiment of the present invention;

FIG. 22 illustrates a dynamic PV module having a module of 75 stacks of 6 cells each with adjusted current and voltage to compensate for a decrease in the module voltage due to environmental factors in accordance with an embodiment of the present invention;

FIG. 23 illustrates a dynamic PV module having stacks of 6 cells each with adjusted dimensions for adjusting current and voltage to compensate for a decrease in the module voltage and/or decrease in the module current due to environmental factors in accordance with an embodiment of the present invention; and

FIG. 24 illustrates a dynamic PV module having a module of 60 stacks of 6 cells each with redundant bypass diodes connected in parallel to the bypass diodes connected in parallel to the cell stacks in accordance with an embodiment of the present invention.

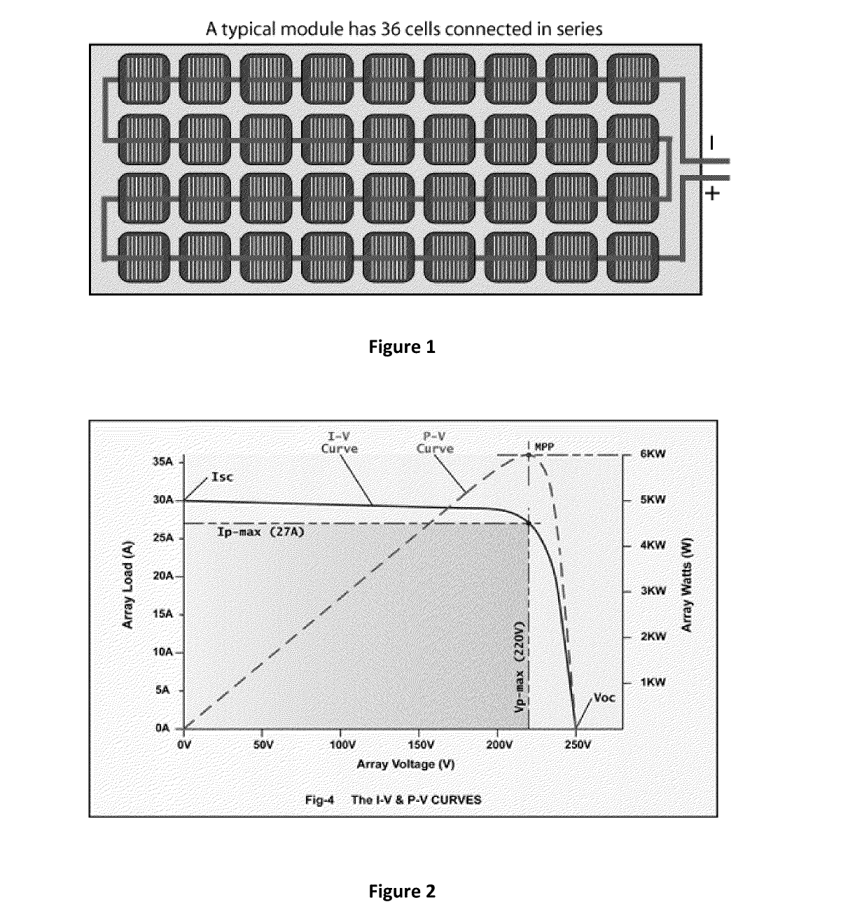

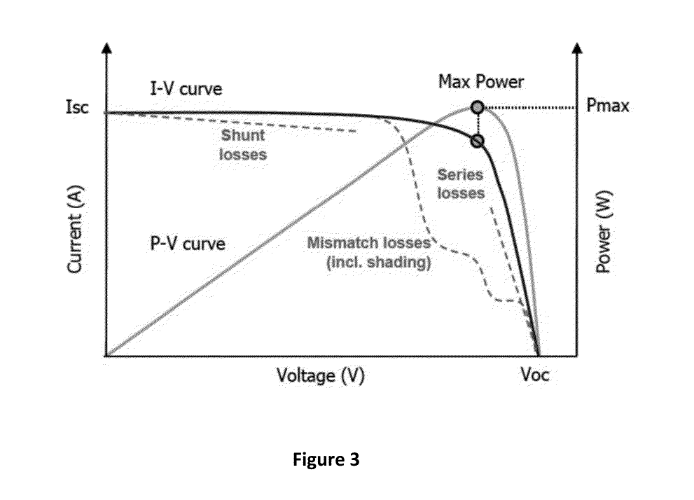

### DETAILED DESCRIPTION OF THE INVENTION

The invention solution is based on new module architecture using internal solar cells structure. A new design of solar cell is introduced.

The solar cell, of any size, will be cut into several equal sizes, called sub-cells which are connected together in parallel as stack, called cell-stack. Balancing bus-bars will be introduced to maintain same voltage a cross all sub-cells in the stack. So, all sub-cells will be connected in parallel between the two balancing bus-bars. The cell-stack will have the same electrical characteristic of original solar cell but is different in physical dimensions. There might be some improvement in efficiency due usage of smaller sizes cells, sub-cells, with narrower bus-bars which both increase the exposed area and reduces series power loss and voltage drop. All cell-stack will be connected in series and as straight line. It will be encapsulated, as normal PV module, between glass to glass or glass to back sheet with EVAs. The module terminals will be connected to junction box. Bypass diodes will be added to increase protection and dynamicity. Additional parallel bypass diodes can be added for protection redundancy.

The concept can be partially applied in case of having two or more straight groups of cell-stacks placed in parallel and connected in serial within the same module, although it is less recommended.

The dynamic PV module comprises a series-parallel cells (sub-cells) interconnection, in order to create more paths for module current to pass-through in case of any blocking at any point to avoid any current mismatch, energy loss, power dissipation and hot spot formation.

There are several aspects to be taken into consideration while designing a dynamic PV module in accordance with this invention. Each of these aspects is impacted by certain factors as detailed in table 1 below.

TABLE 1

| Design Aspects | Factors |
|---|---|
| Power Output | Size of Module |
| | Efficiency of solar cells |
| | Number of sub-cells in cell-stack |
| Dependency Ratio | Number of sub-cells in cell-stack |
| | Dependency Ratio = |
| | (1/Number of sub-cells in cell-stack) * 100 |
| Dynamicity | Dependency Ratio (The smaller is better) Number |
| | of cell-stacks that are protected by |
| | each bypass diode (the smaller is better) |
| Module voltage | The voltage of original solar cell |
| | Number of cell-stack in PV module |
| Module current | The current of original solar cell |
| | Number of sub-cells in cell-stack |

The process of designing a Dynamic PV module comprises the steps of choosing the type of solar cells, determining the dependency ratio, determining the sub-cell specification, determining the cell-stack specification and determining the module surface area. These determinations depend on the design aspects specified in Table 1.

Original solar cell: this consists of choosing the type of solar cell that is going to be used in the module production. The electrical and thermal characteristics of the used solar cell type will make the major contribution to module electrical and thermal characteristics and in turn its performance. The original solar cell will be cut into symmetrical sub-cells to be used in the Dynamic PV module. Laser or other suitable cutting techniques can be used to cut the original solar cell into sub-cells. Thin film cells will have different approach based on the same concept.

Dependency ratio: it can be determined by defining the number of sub-cells per cell-stack, the higher sub-cell number per cell-stack, the lower cell to cell dependency ratio and the higher dynamicity. There is an advantage of having the highest dependency ratio possible for purposes of increasing the efficiency of the PV module.

Sub-cell specification: The original solar cell will be laser cut into symmetrical sub-cells (strip shape). The number of sub-cells from original solar cell will be defined based on the selected dependency ratio, as mentioned above. For example if dependency factor is (⅙=16.7%) then original solar cell 6″×6″ will be laser cut into 6 sub-cells of size 6″×1″ (strips, length 6″ & width 1″). In this case, the sub-cell electrical parameters, with respect to the original solar cell, are ⅙ of power, same voltage and ⅙ of current of the original solar cell.

Cell-stack specification: the original solar cell will be laser cut into sub-cells. Sub-cells will be arranged vertically and connected in parallel between two balancing bus-bars to form cell-stack. Cell stack length will be obtained by multiplying the number of sub-cell by sub-cell length. Cell-stack width is similar to sub-cell width. In this case, cell-stack electrical specification should be equal to original solar cell in terms of power, current and voltage.

Module Power: it can be determined through multiplying the cell-stack power (original solar cell power) by number of cell-stacks in the module.

Module surface area: module length will equal to cell-stack length plus borders. Module width equal to number of cell-stacks in module multiplied by cell stack width, plus borders width.

Module voltage: it can be obtained from cell-stack voltage (original solar cell voltage) multiplied by the number of series cell-stacks in the module.

Module current: it can be obtained from current of a sub-cell multiplied by the number of sub-cells per stack (parallel current summation), which should be equal to original solar cell current.

Bypass Diodes: a number of bypass diodes can be added in parallel to the cell-stacks for extreme protection and improvement of dynamicity. The minimum number of bypass diodes can be one per module, however preferably would go up to one per each cell-stack. This would impact the costs however. An optimum number of bypass diode can be chosen to cover a group of series cell stacks together.

Redundant bypass diode set: an additional lower number of bypass diodes can be added on parallel to the proposed main bypass diodes to add redundant protection.

Spacing tolerance should be considered while specifying dimensions. The overall electrical characteristic of the module like I-V curve is expected to be look like the original solar cell characteristic in shape. At testing under STC, an improvement in power components like current and voltage would be obtained due this new cell architecture connection over the traditional cell string connection. The firm module specification and dimension will be known after fabrication and testing of first units of the designed module.

Design flexibility for module power components V & I (V & I Transformation):

It is known that the DC power value is the product of DC voltage by DC current (P=V×I). The value of DC power can stay the same while the values of its components DC voltage and DC current can vary but both in opposite directions of each other (increasing and decreasing).

With respect to the same PV module surface area, power output and dynamicity factor, the two power components voltage “V” and current “I” can be changed or adjusted at the design stage. In a normal module system, when there is a need to increase the voltage and reduce the current to suit the voltage range of solar inverter or to match the voltage of inverter peak efficiency, the solution is to use a 5″×5″ cells instead of 6″×6″ cells to increase the number of solar cells per module and in turn increase the summation of cells voltage in series that produce the module voltage.

The dynamic PV module according to this invention may enable the feature of increasing voltage and decreasing current or vice versa, with respect to the same module surface area and out power, at the designing stage, in order to let module specification suit different usage applications and project locations. This is for example to take account of the impact of the environmental temperature and light radiance on the module voltage and current. In fact, a high environmental temperature (resulting in a high module temperature) can result in a decrease in the module voltage and a high environmental light radiance (resulting in radiance exposure to the module) can result in a increase in the module current.

The solution idea behind that is to change the width of sub-cells with respect to the standard width used in a standard dynamic PV module. This in turn changes the cell-stack width and number of cell-stacks that can be accommodated in module at given surface area and power rating. Then the change of module voltage and current is possible. In other terms, the width of sub cells in cell stack and the number of cell stacks per module should be determined in order to adjusting the module current and voltage taking into consideration the effect of the environmental conditions (mainly temperature and light radiance intensity) on these, for application in specific region.

In case the sub-cell width is increased beyond the standard width while its length is the same, then cell-stack width and area increase and it will be able to produce greater current which represents the module current. At the same time, the number of cell-stacks that can be accommodated within the given module area becomes smaller and therefore module voltage becomes lower. The overall power and module area will stay the same (P=V×I). On opposite way, in case sub-cell width is decreased below the standard width while its length is the same, then cell-stack width and area are decreased and it will produce less current which represents the module current. At the same time, the number of cell-stack that can be accommodated within the given module area becomes greater and therefore module voltage becomes higher. In all cases, the module area, power output and dynamicity will stay the same.

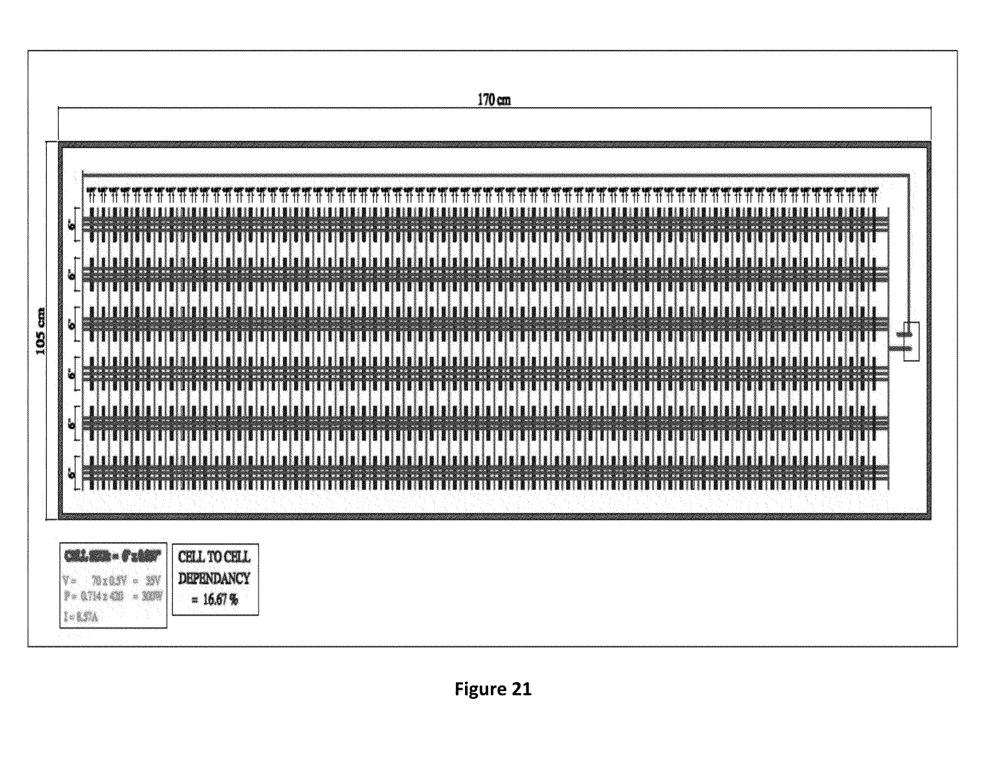

Note that, this concept is demonstrated in voltage and current transformation with aid of FIGS. 21, 22 and 23.

Possible Applications and Project Locations of Voltage Flexibility Feature

A solar inverter is used to convert the output DC power generated from PV modules into an AC power form that suit the grid. Solar inverter has an operating DC input voltage range (VDCₘᵢₙ . . . VDCₘₐₓ), beyond that it will not be able to work, switch-off. Within this operating voltage range there is another shorter voltage range called MPPT input DC voltage range (V_{MPPTmin} . . . V_{MPPTmax}). Only at MPPT “Maximum Power Point Tracking” input DC voltage range, the solar inverter is able to work at its maximum conversion efficiency. A solar PV system should be designed so that its output voltage is varying within the MPPT DC input voltage range of the inverter during different operating conditions. This is to insure maximum energy harvesting, and at same time to avoid any output DC voltage beyond the inverter operating DC input voltage range.

In general, the Dynamic PV Modules will help solar PV system to stabilize the input DC voltage to the solar inverter through mitigation of external impacts and to reduce DC voltage drop in side modules (by reducing series resistances). This will help to keep solar PV system working within the MPPT input DC voltage range of the solar inverter at different operating conditions. Additional advantage, at the module designing stage, Dynamic PV Module design can be adjusted to generate DC power with pre-specified voltage and current (as described earlier) that suits certain applications and/or different project locations. This is called Module design voltage flexibility feature.

### Dynamic PV Module Voltage Flexibility Feature and Project Location Conditions Relation

As it well-known in the PV science, the module current intensity is linearly proportional to the sun light intensity while the module voltage is not significantly impacted by the sun light intensity. Also, though the increase in the module temperature can result in a slight increase in the module current, the module temperature increase can inversely affect the voltage of the module resulting in a reduction in voltage. Therefore, environmental light intensity and temperature can have an effect on the performance (current/voltage) of PV modules. In other terms, a high light intensity expose would result in an increase of a current of the module and high temperature expose would result in a reduction of the voltage in the module.

On light of these considerations, the dynamic PV module design can be adjusted in order to take into consideration the temperature characteristics of the geographical region where the PV module is to be implemented in such a manner to compensate back for these losses in current and/or voltage. In hot countries for example, the width of the sub-cells can be reduced in order to form a bigger number of cell stacks which would result in an increase in the module voltage to compensate for the voltage loss the raise in temperature would cause. Also, in cold countries experiencing low radiation (light), the width of the sub-cells can be increased in order to increase the current of the module which is determined by the current of the stack cell.

In middle areas where sun light intensity and temperature are on average (moderate), a standard module power specification can be used. In cold areas where the climate temperature is low and light intensity is lower than usual, in this case the proper design is to have module with lower voltage and higher current with respect the standard module design. Recall that low module temperature will tend to increase module voltage and low light intensity will reduce module current than rated. This will help to improve the performance of the module and make it fit more with the solar inverter input DC voltage range. In hot areas, like arid region, where the temperature is too high and sun light intensity is closer to higher limit. In this case, the proper module design is to have module with higher module voltage and lower module current with respect to the standard module design that has same surface area and rated output power. Recall that high module temperature will tend to reduce module voltage and high light intensity will increase module current.

### Dynamic PV Module Voltage Flexibility Feature and Type of Application Relation:

With high efficient solar cells: The latest improvement in solar cells moves in the direction of producing cells with higher efficiencies. These cells usually tend to produce higher current under standard test conditions. The normal practice, with standard size conventional PV module, is to use 5″×5″ solar cells instead of 6″×6″ solar cells in order to manage this increase in current and produce proper accumulated module voltage that suit the inverter. With the introduction of Dynamic PV Module Concept, this issue can be managed with usage of sub-cell with shorter width to increase the number of cell stacks within same module area and in turn increase the module voltage greater than standard. In the same time it will reduce module current less than the standard, without any reduction in power (P=V×I). This current reduction will also let the solar system has lower internal power loss and voltage drop. The new module will be more efficient and its voltage more suitable for solar inverters.

With solar power concentration on PV system (CPV): Solar power concentrators are used to concentrate sun light onto smaller area of solar technology. The concentration ratio can be measured with the number of suns concentrated on the solar receiver. The conventional solar cells can work with low sun concentration, few tens of suns. Under sun concentration, the power produced has very high current (due to high sun light intensity) at standard or lower voltage (due to increase in temperature). To have PV module with higher voltage and low current at rated power, the voltage flexibility feature of the dynamic PV modules can help in design stage to adjust the power parameters voltage and current that required for solar power concentration enabling PV module to work effectively in solar power concentration.

Semi-Transparent Dynamic PV module: It is a glass to glass semi-transparent PV module, usually without borders. It is used as a roof of the green house and other application. The dynamic PV module concept is applied to the module's cell architecture. The transparency percentage will be determined based on the spacing, displacement, between each two cell-stacks. In case of solar PV green house, the suitable transparency percentage will differ based on the geographical location (light intensity) and plantation types (best growth rate) inside the green house. The semi-transparent dynamic PV module can be used for other applications as well like carport, canopy and building integrated shaded terraces.

Solar energy capturing concept: it describes techniques that enable full capturing of solar irradiation and direct them toward integrated solar technology using fixed system, no sun tracker. The system will work as a sun light concentrator with no moving parts, in order to maximize the energy yield and create new applications.

The solar energy capturing concept will be an integration of Dynamic PV Modules with solar reflector sheets, like Aluminum composite sheet reflector. They will be connected together with an angle between them like V shape. The Dynamic PV modules and solar reflectors array is extended in east west directions. The tilt angles for Dynamic PV module and its reflector are specified as per the site latitude and the preferred time of the year for maximum production. These arrays can be attached together, without spacing for shade tolerance, to form a surface. This surface can be a ground mounted or roof top solar system, however, it can be used as the roof itself in some cases like the mentioned in next applications.

Applications:

The solar power technology will be incorporated with the elements of the new solar concept system. New solar concept system will be integrated with real human project to double utilize land and gain cost reduction for both in terms of land cost, land leveling and construction cost. Although it can be used as roof top or ground mounted project, however for double utilization of the site, it is better to be used as a building integrated solution since it can represent part of the building. The solar system can be applied among others on these types of projects: solar PV green houses, livestock houses, warehouses, workshops, showrooms, cheap solar car parking, countryside houses and others.

### Examples

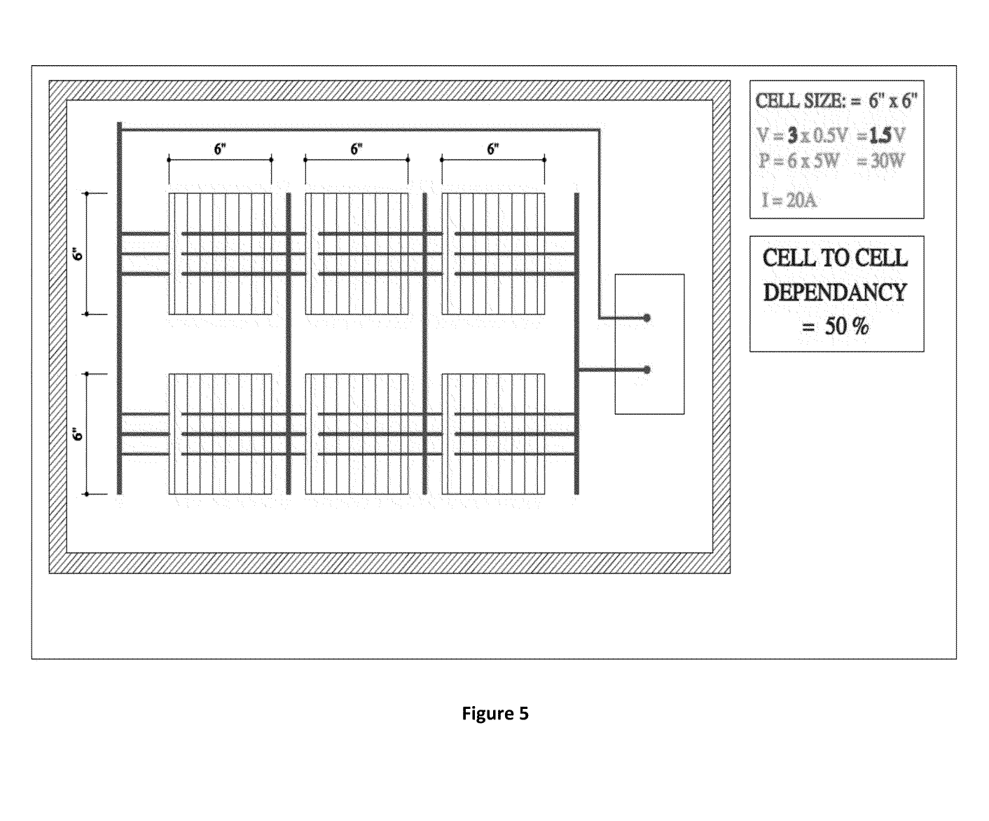

As an example of implementation of a dynamic PV module in accordance with an embodiment of the present invention, FIG. 5 illustrates a dynamic PV module having 3 stacks of 2 PV cells each. The specifications of the PV module are as follow:

| | |
|---|---|
| Cell size | 6″ × 6″ |
| Voltage | V = 3 × 0.5 V = 1.5 V |
| Power | P = 6 × 5 W = 30 W |
| Current | I = 20 A |
| Cell-to-Cell Dependency | 50% |

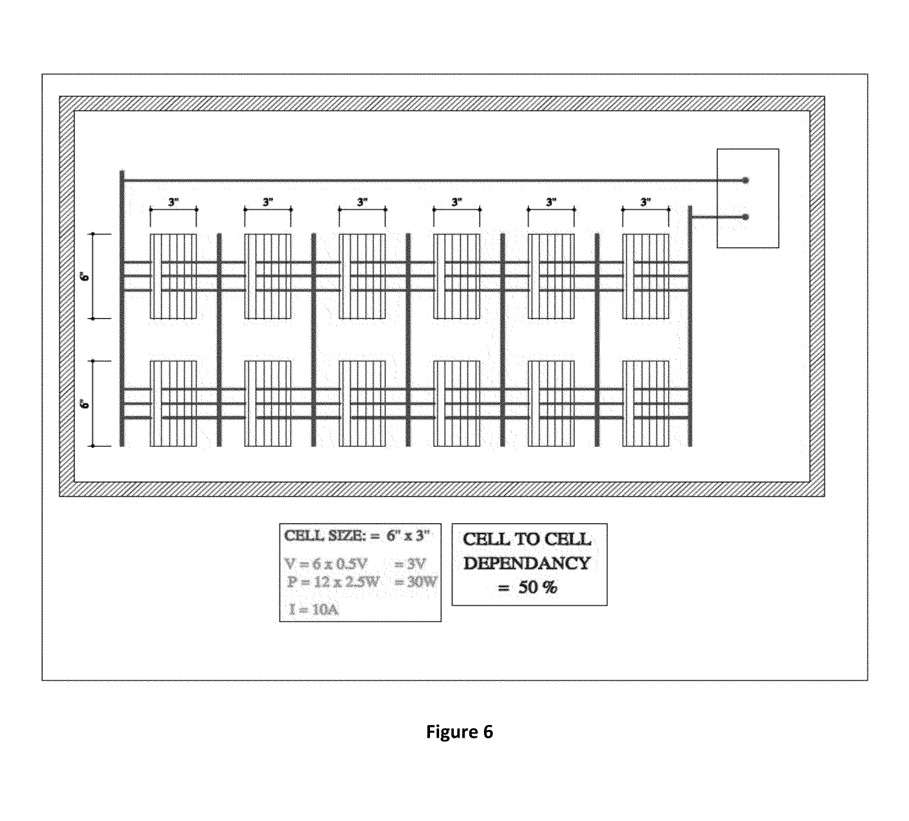

As an example of implementation of a dynamic PV module in accordance with an embodiment of the present invention, FIG. 6 illustrates a dynamic PV module having 6 stacks of 2 PV cells each. The specifications of the PV module are as follow:

| | |
|---|---|
| Cell size | 6″ × 3″ |
| Voltage | V = 6 × 0.5 V = 3 V |
| Power | P = 12 × 2.5 W = 30 W |
| Current | I = 10 A |
| Cell-to-Cell Dependency | 50% |

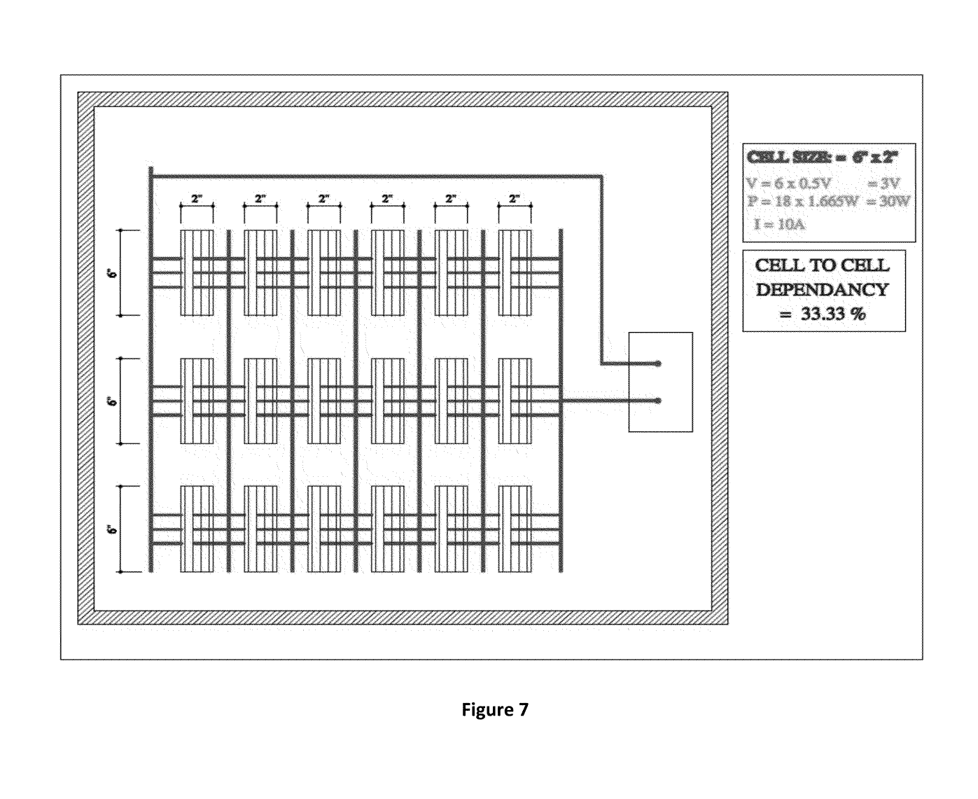

As an example of implementation of a dynamic PV module in accordance with an embodiment of the present invention, FIG. 7 illustrates a dynamic PV module having 6 stacks of 3 PV cells each in accordance with an embodiment of the present invention. The specifications of the PV module are as follow:

| | |
|---|---|
| Cell size | 6″ × 2″ |
| Voltage | V = 6 × 0.5 V = 3 V |
| Power | P = 18 × 1.665 W = 30 W |
| Current | 10 A |
| Cell-to-Cell Dependency | 33.33% |

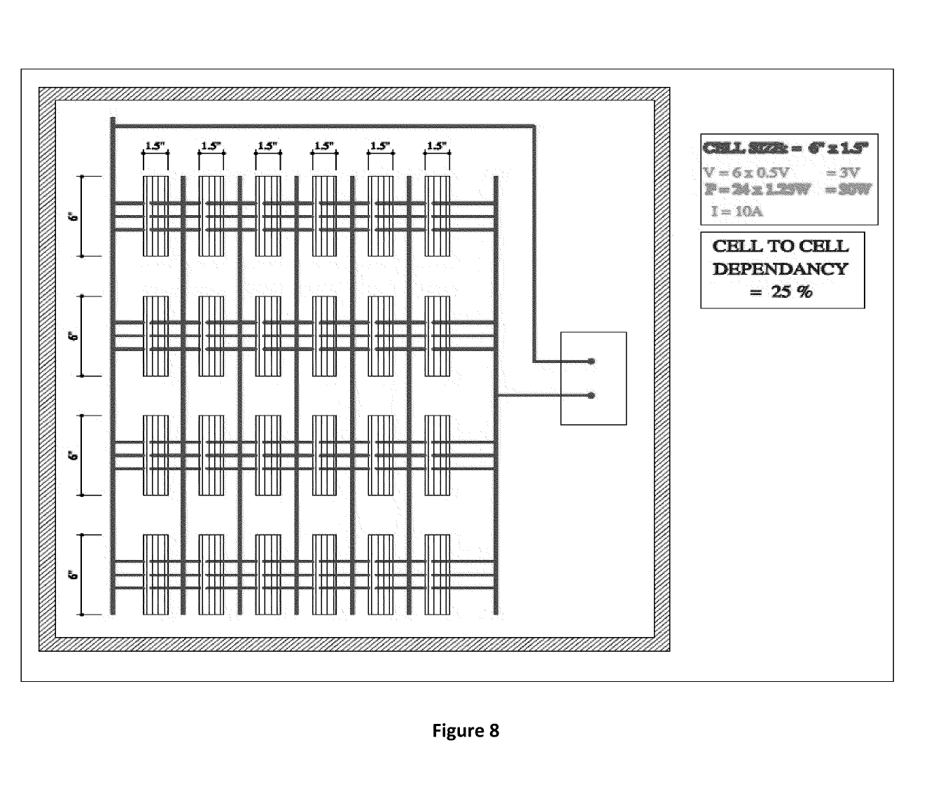

As an example of implementation of a dynamic PV module in accordance with an embodiment of the present invention, FIG. 8 illustrates a dynamic PV module having 6 stacks of 4 PV cells each in accordance with an embodiment of the present invention. The specifications of the PV module are as follow:

| | |
|---|---|
| Cell size | 6″ × 1.5″ |
| Voltage | V = 6 × 0.5 V = 3 V |
| Power | P = 24 × 1.25 W = 30 W |
| Current | 10 A |
| Cell-to-Cell Dependency | 25% |

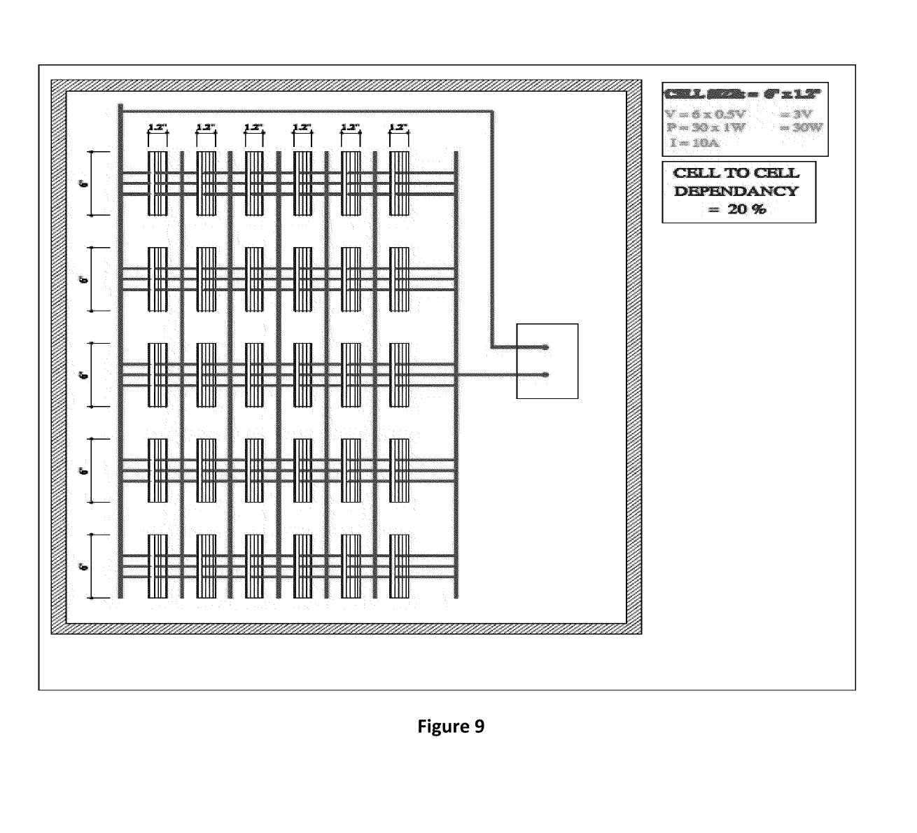

As an example of implementation of a dynamic PV module in accordance with an embodiment of the present invention, FIG. 9 illustrates a dynamic PV module having 6 stacks of 5 PV cells each in accordance with an embodiment of the present invention. The specifications of the PV module are as follow:

| | |
|---|---|
| Cell size | 6″ × 1.2″ |
| Voltage | V = 6 × 0.5 V = 3 V |
| Power | P = 30 × 1 W = 30 W |
| Current | 10 A |
| Cell-to-Cell Dependency | 20% |

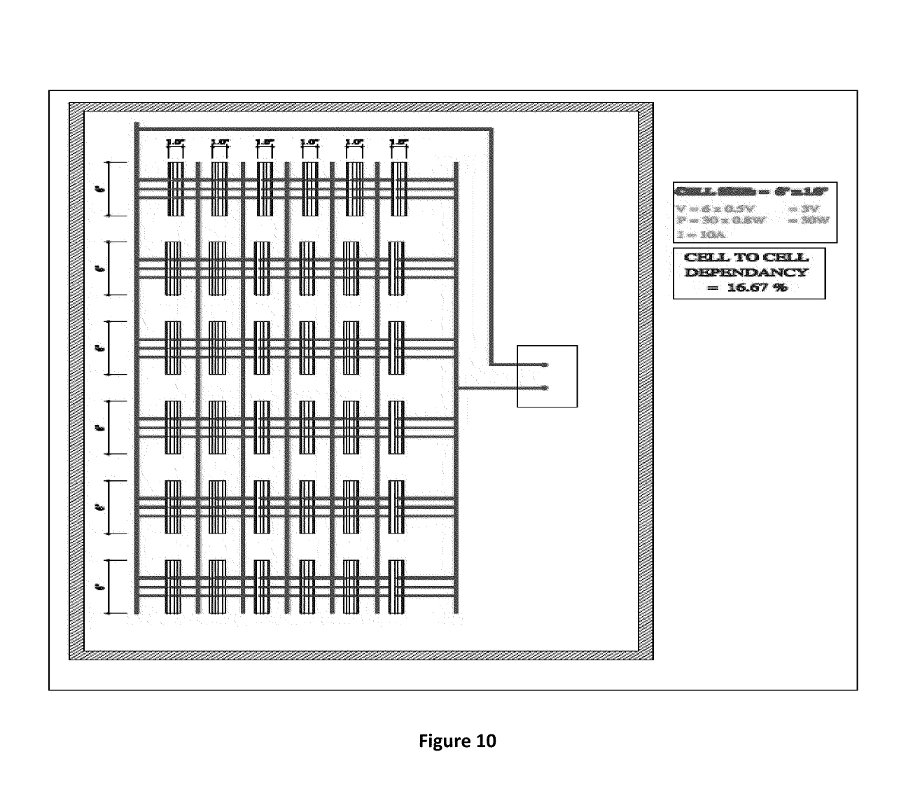

As an example of implementation of a dynamic PV module in accordance with an embodiment of the present invention, FIG. 10 illustrates a dynamic PV module having 6 stacks of 6 PV cells each in accordance with an embodiment of the present invention. The specifications of the PV module are as follow:

| | |
|---|---|
| Cell size | 6″ × 1.0″ |
| Voltage | V = 6 × 0.5 V = 3 V |
| Power | P = 30 × 0.8 W = 30 W |
| Current | 10 A |
| Cell-to-Cell Dependency | 16.67% |

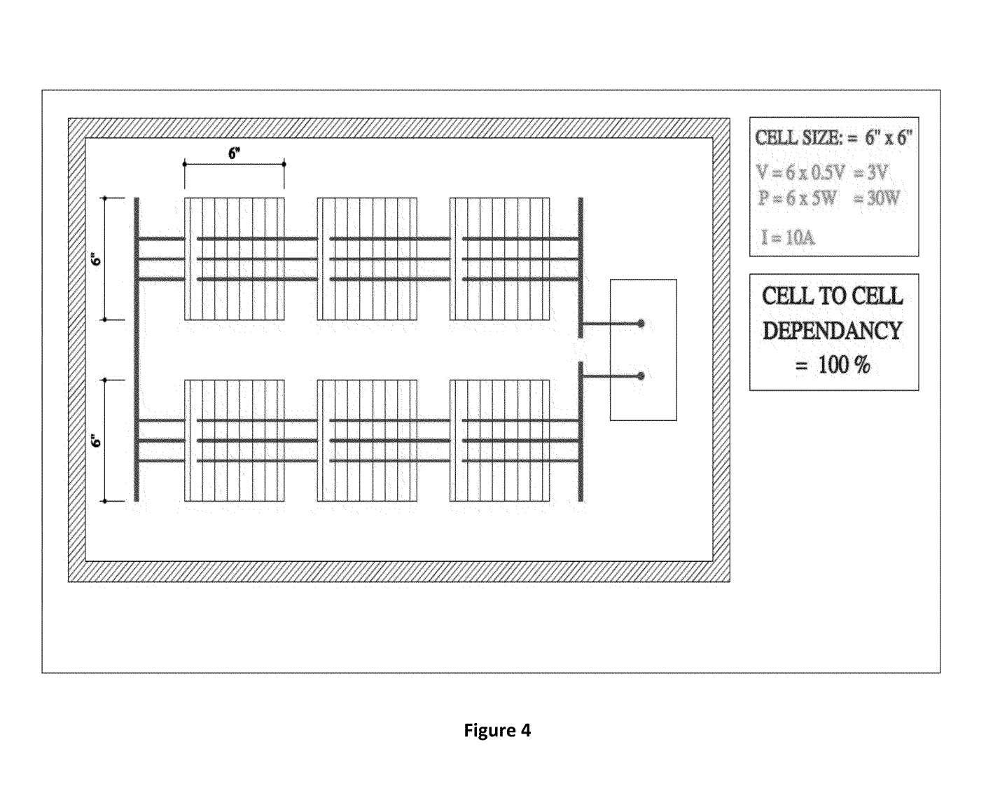

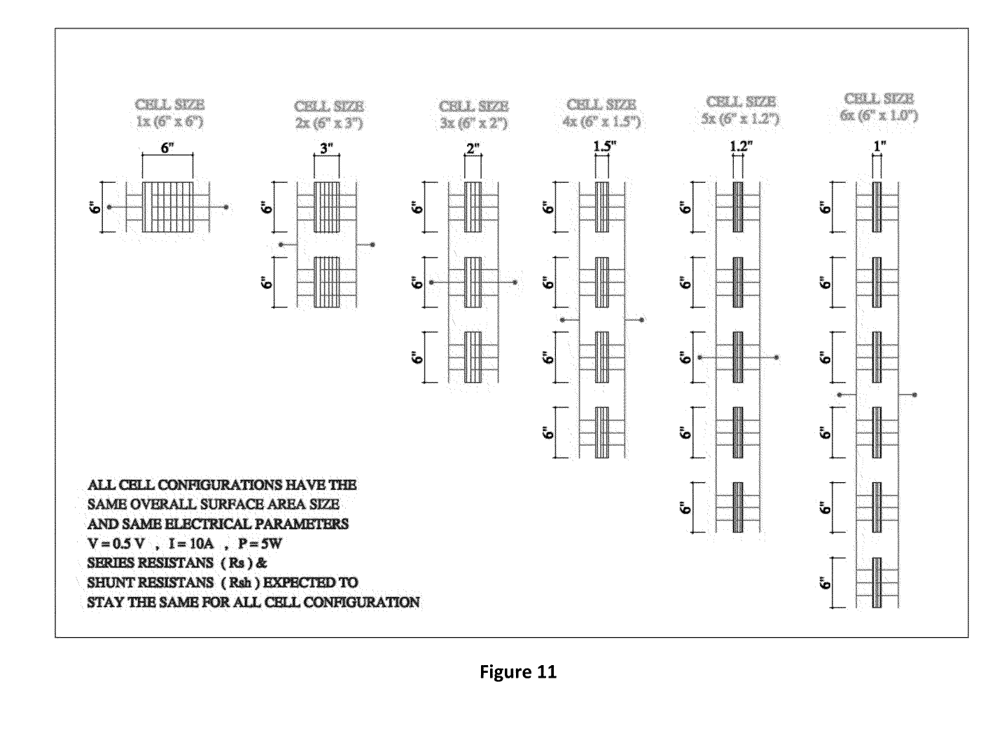

FIG. 11 illustrates that all stack configurations of the examples presented above in FIGS. 4 and 6-10 are produced from the original solar cell. The original solar cell 6″×6″ has been cut into several equal strips (sub-cells) and reassembled in different cell-stacks sizes that have the same overall cell surface area size and same electrical parameters (with V=0.5 V, I=10 A and P=5 W as example). The series resistants (Rs) and shunt resistant (Rsh) of all cell stack configurations are expected to stay the same.

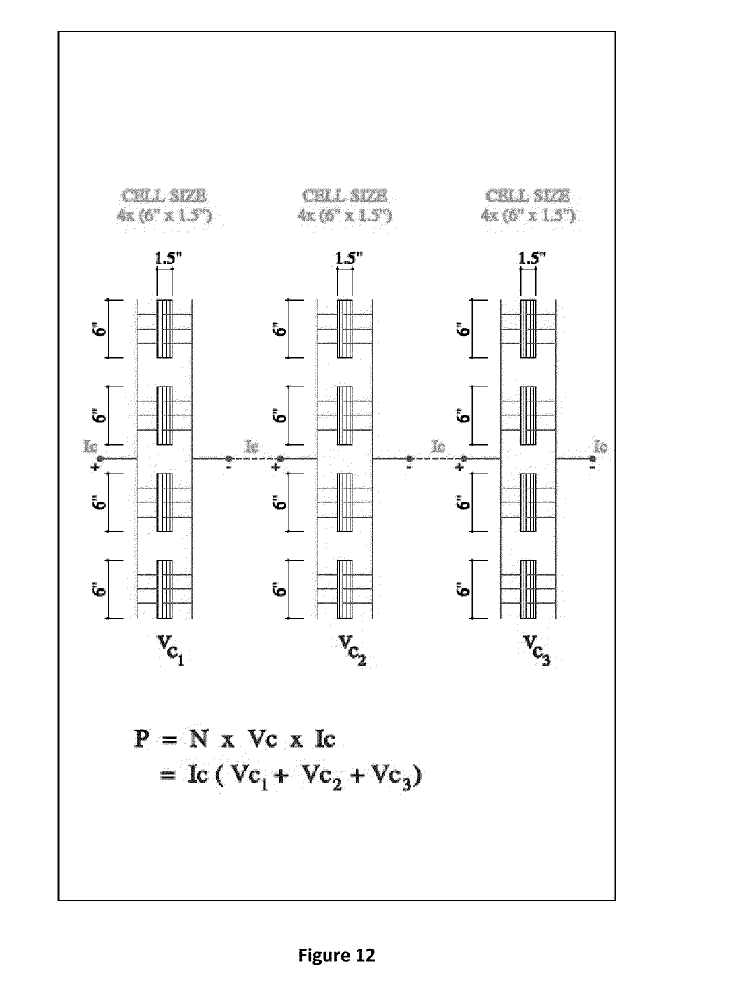

FIG. 12 illustrates the current, voltage and power in a dynamic PV module having 3 stacks of 4 cells each in accordance with an embodiment of the present invention. It shows that the module voltage is the sum of the voltages of the individual stacks and the module current is equal to the stack current at the output.

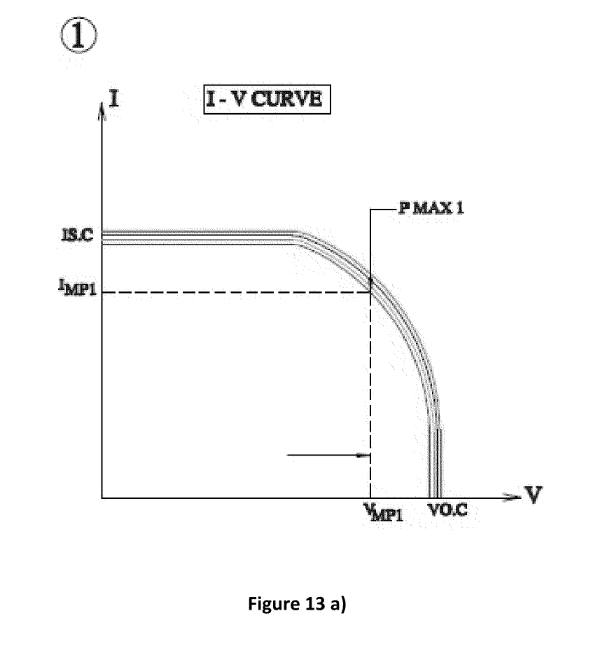

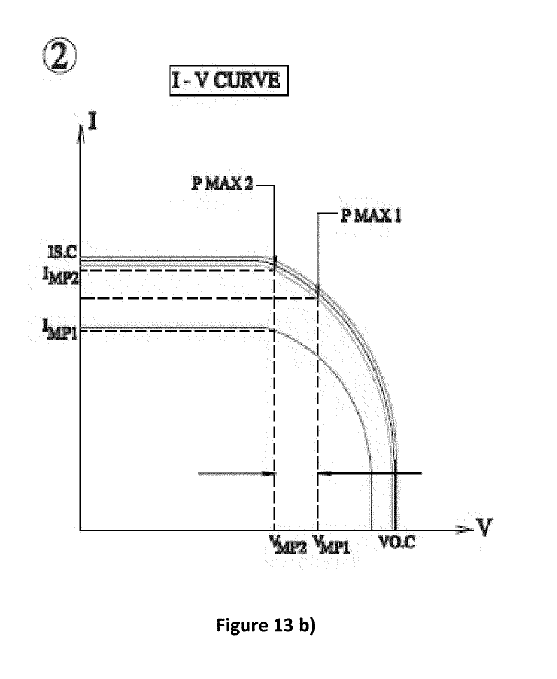

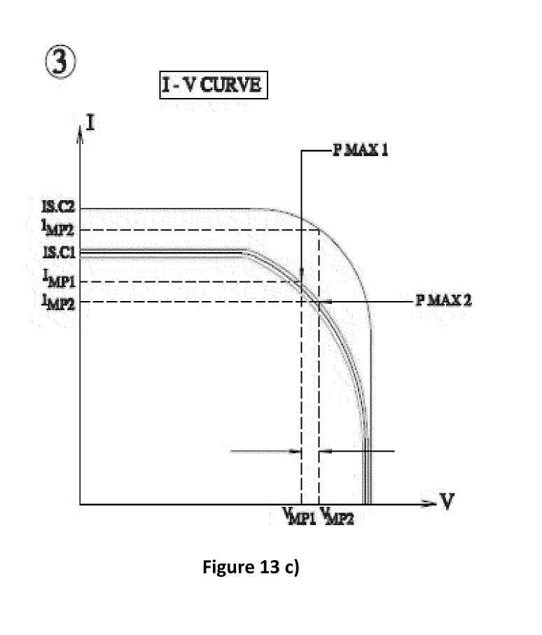

FIG. 13 a), b) and c) illustrates the I-V Curves of the different performance of cell-stacks receiving different light intensities within same PV module in accordance with an embodiment of the present invention. With reference to FIG. 12 and cell-stack number 1, 2 & 3 assuming these conditions which are represented in FIG. 13 a), b) and c) respectively. First, all sub-cells in cell-stack 1 are typical and receive same light intensity, they will produce same current to fulfill module current to pass through at standard voltage of maximum power point (see FIG. 13 a)). Second, all sub-cells in cell-stack 2 are typical and one of them receive less light compared with others, they will change their operating point at maximum power point to another operating point at which their current summation fulfill module current value to pass through but at lower voltage (see FIG. 13 b)). Third, all sub-cells in cell-stack 3 are typical and one of them receive more light compared with others, they will change their operating point at maximum power point to another operating point at which their current summation fulfill module current value to pass it through but at higher voltage (see FIG. 13 c)). The module current value will stay the same, without current mismatch loss, and module voltage will be the summation of all cell-stack voltages.

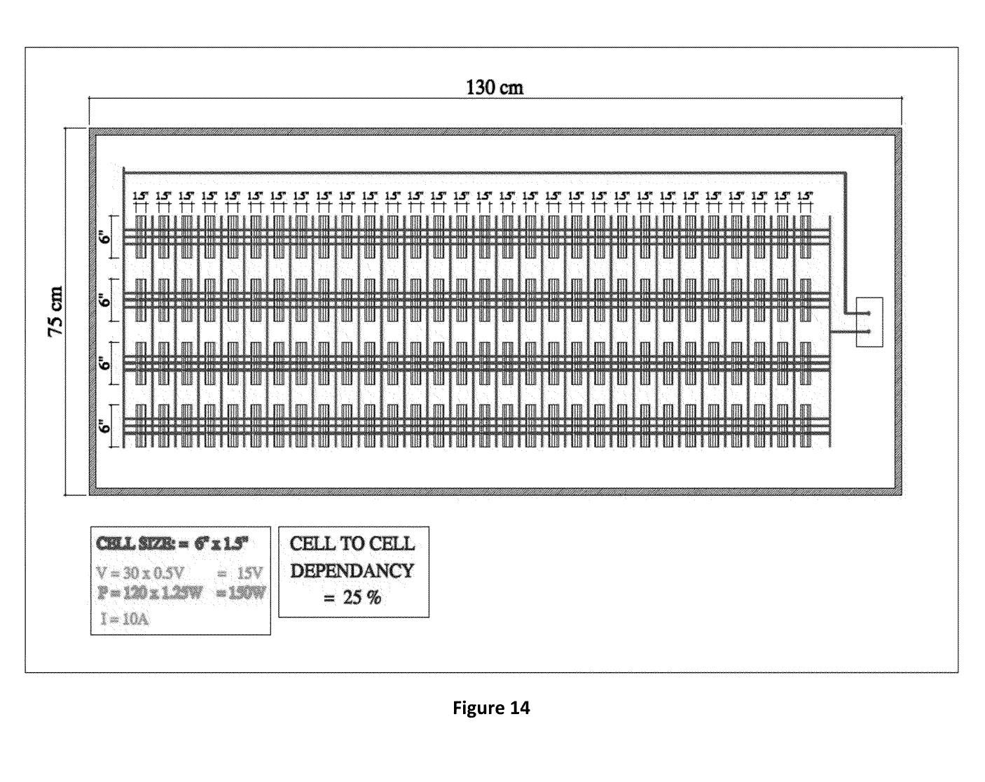

As an example of implementation of a dynamic PV module in accordance with an embodiment of the present invention, FIG. 14 illustrates a dynamic PV module having 30 stacks of 4 cells each in accordance with an embodiment of the present invention. The specifications of the PV module are as follow:

| | |
|---|---|
| Cell size | 6″ × 1.5″ |
| Voltage | V = 30 × 0.5 V = 15 V |
| Power | P = 120 × 1.25 W = 150 W |
| Current | 10 A |
| Cell-to-Cell Dependency | 25% |

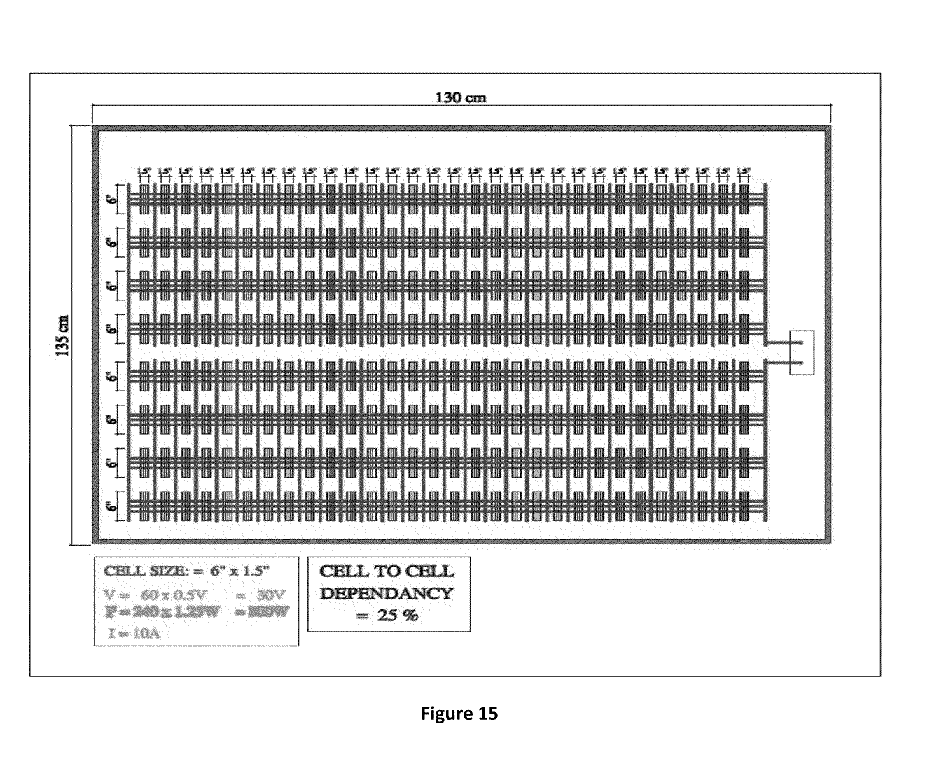

As an example of implementation of a dynamic PV module in accordance with an embodiment of the present invention, FIG. 15 illustrates a dynamic PV module having 2 sub modules of 30 stacks of 4 cells each where the sub modules are connected in parallel each in accordance with an embodiment of the present invention. The specifications of the PV module are as follow:

| | |
|---|---|
| Cell size | 6″ × 1.5″ |
| Voltage | V = 60 × 0.5 V = 30 V |
| Power | P = 240 × 1.25 W = 300 W |
| Current | 10 A |
| Cell-to-Cell Dependency | 25% |

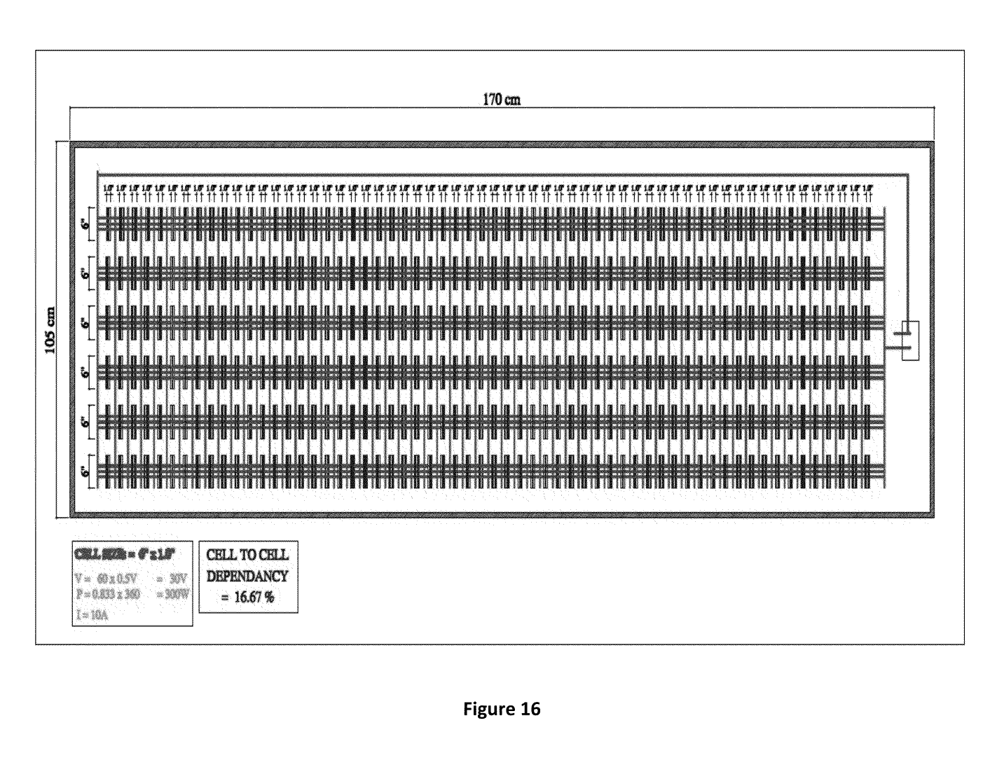

As an example of implementation of a dynamic PV module in accordance with an embodiment of the present invention, FIG. 16 illustrates a dynamic PV module having a module of 60 stacks of 6 cells each in accordance with an embodiment of the present invention. The specifications of the PV module are as follow:

| | |
|---|---|
| Cell size | 6″ × 1.5″ |
| Voltage | V = 60 × 0.5 V = 30 V |
| Power | P = 0.833 × 360 = 300 W |
| Current | 10 A |
| Cell-to-Cell Dependency | 16.67% |

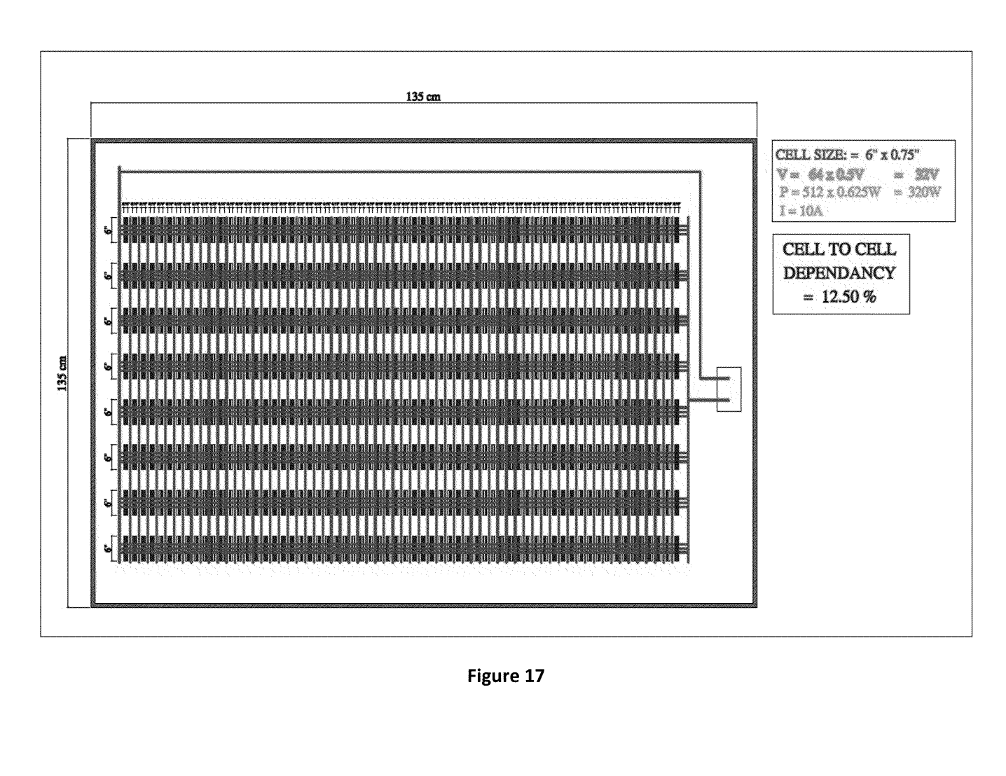

As an example of implementation of a dynamic PV module in accordance with an embodiment of the present invention, FIG. 17 illustrates a dynamic PV module having a module of 64 stacks of 8 cells each in accordance with an embodiment of the present invention. The specifications of the PV module are as follow:

| | |
|---|---|
| Cell size | 6″ × 0.75″ |
| Voltage | V = 64 × 0.5 V = 32 V |
| Power | P = 512 × 0.625 W = 320 W |
| Current | 10 A |
| Cell-to-Cell Dependency | 12.50% |

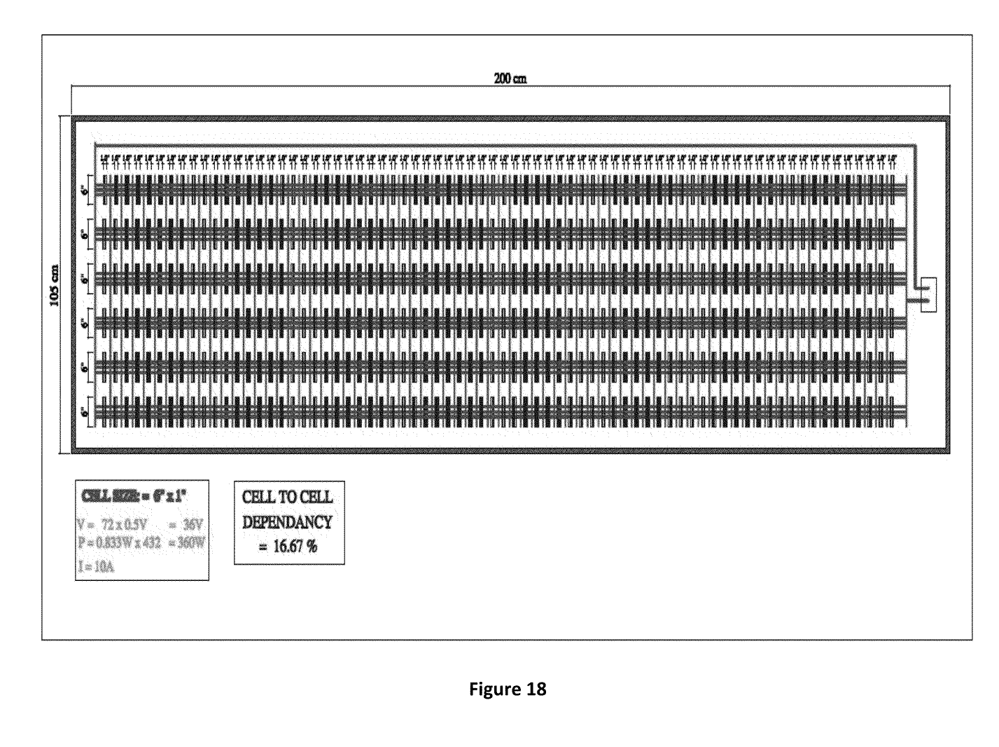

As an example of implementation of a dynamic PV module in accordance with an embodiment of the present invention, FIG. 18 illustrates a dynamic PV module having a module of 72 stacks of 6 cells each in accordance with an embodiment of the present invention. The specifications of the PV module are as follow:

| | |
|---|---|
| Cell size | 6″ × 1″ |
| Voltage | V = 72 × 0.5 V = 36 V |
| Power | P = 432 × 0.833 W = 360 W |
| Current | 10 A |
| Cell-to-Cell Dependency | 16.67% |

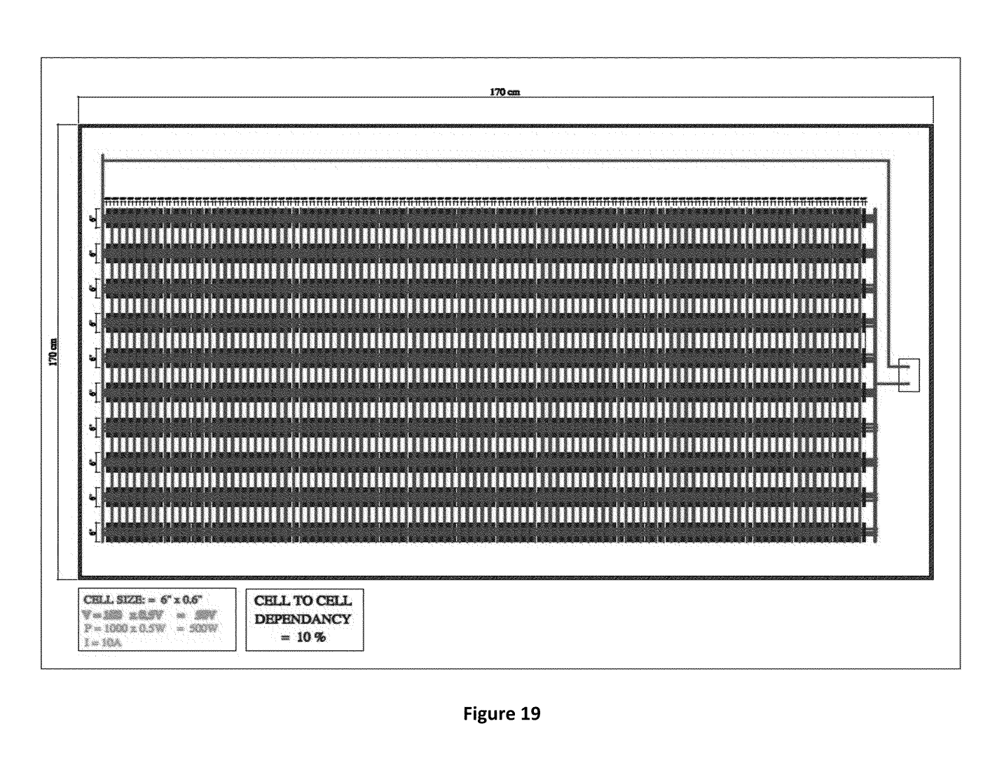

As an example of implementation of a dynamic PV module in accordance with an embodiment of the present invention, FIG. 19 illustrates a dynamic PV module having a module of 100 stacks of 10 cells each in accordance with an embodiment of the present invention. The specifications of the PV module are as follow:

| | |
|---|---|
| Cell size | 6″ × 0.6″ |
| Voltage | V = 100 × 0.5 V = 50 V |
| Power | P = 1000 × 0.5 W = 500 W |
| Current | 10 A |
| Cell-to-Cell Dependency | 10% |

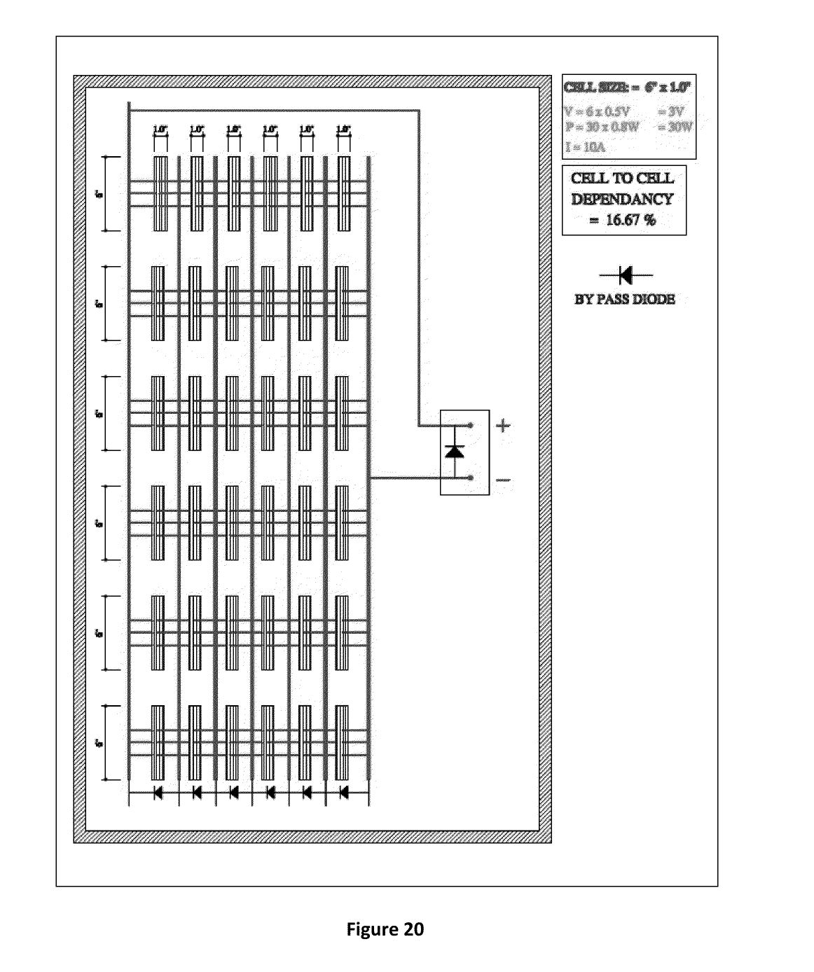

As an example of implementation of a dynamic PV module in accordance with an embodiment of the present invention, FIG. 20 illustrates a dynamic PV module having a module of 6 stacks of 6 cells each with by-pass diodes connected in parallel between adjacent stacks in accordance with an embodiment of the present invention. A redundant bypass diode for redundant module protection is connected between its terminals. The specifications of the PV module are as follow:

| | |
|---|---|
| Cell size | 6″ × 1.0″ |
| Voltage | V = 6 × 0.5 V = 3 V |
| Power | P = 36 × 0.833 W = 30 W |
| Current | 10 A |
| Cell-to-Cell Dependency | 16.67% |

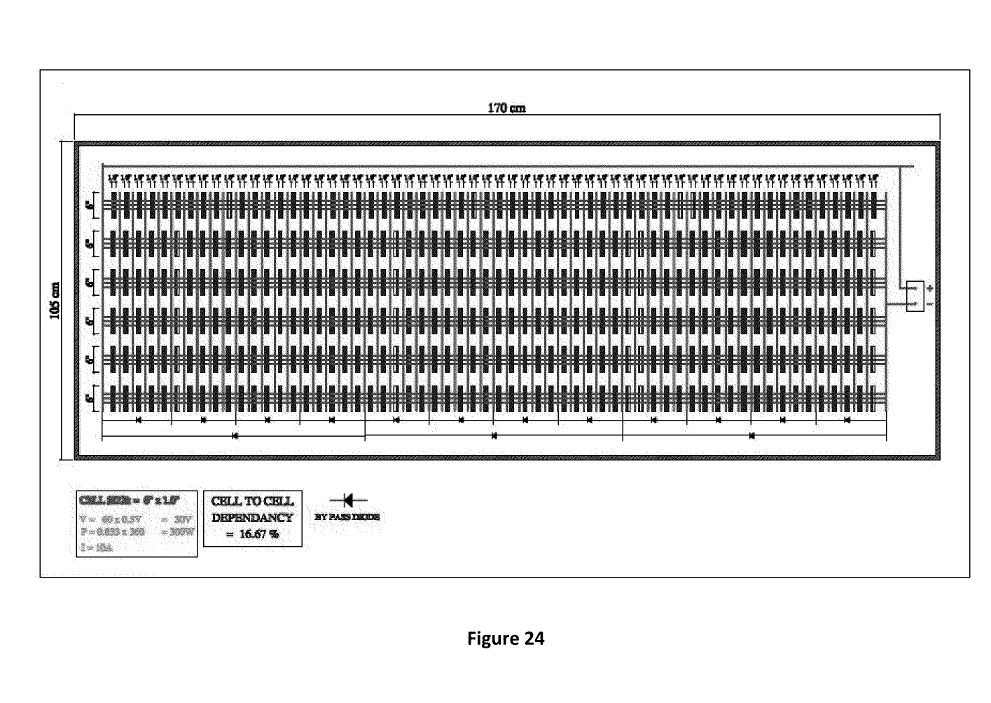

As an example of implementation of a dynamic PV module in accordance with an embodiment of the present invention, FIG. 24 illustrates a dynamic PV module having a module of 60 stacks of 6 cells each with by-pass diodes connected in parallel between adjacent stacks in accordance with an embodiment of the present invention. And redundant bypass diodes for redundant module protection connected in parallel to the bypass diodes. The specifications of the PV module are as follow:

| | |
|---|---|
| Cell size | 6″ × 1.0″ |
| Voltage | V = 60 × 0.5 V = 30 V |
| Power | P = 360 × 0.833 W = 300 W |
| Current | 10 A |
| Cell-to-Cell Dependency | 16.67% |

As an example of implementation of a dynamic PV module in accordance with an embodiment of the present invention, FIG. 21 illustrates a dynamic PV module having a module of 70 stacks of 6 cells each with adjusted current and voltage to compensate for a decrease in the module voltage due to environmental factors in accordance with an embodiment of the present invention. The specifications of the PV module are as follow:

| | |
|---|---|
| Cell size | 6″ × 0.857″ |
| Voltage | V = 70 × 0.5 V = 35 V |
| Power | P = 0.714 × 420 = 300 W |
| Current | 8.57 A |
| Cell-to-Cell Dependency | 16.67% |

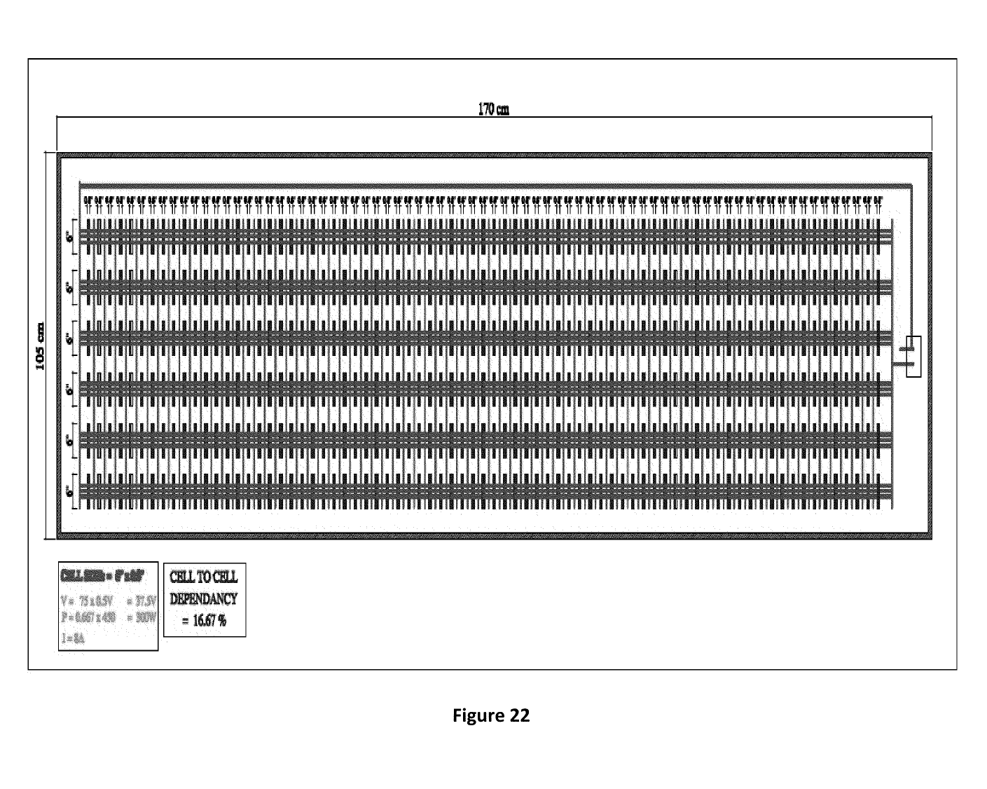

As an example of implementation of a dynamic PV module in accordance with an embodiment of the present invention, FIG. 22 illustrates a dynamic PV module having a module of 75 stacks of 6 cells each with adjusted current and voltage to compensate for a decrease in the module voltage due to environmental factors in accordance with an embodiment of the present invention. The specifications of the PV module are as follow:

| | |
|---|---|
| Cell size | 6″ × 0.8″ |
| Voltage | V = 75 × 0.5 V = 37.5 V |
| Power | P = 0.667 × 450 = 300 W |
| Current | 8 A |
| Cell-to-Cell Dependency | 16.67% |

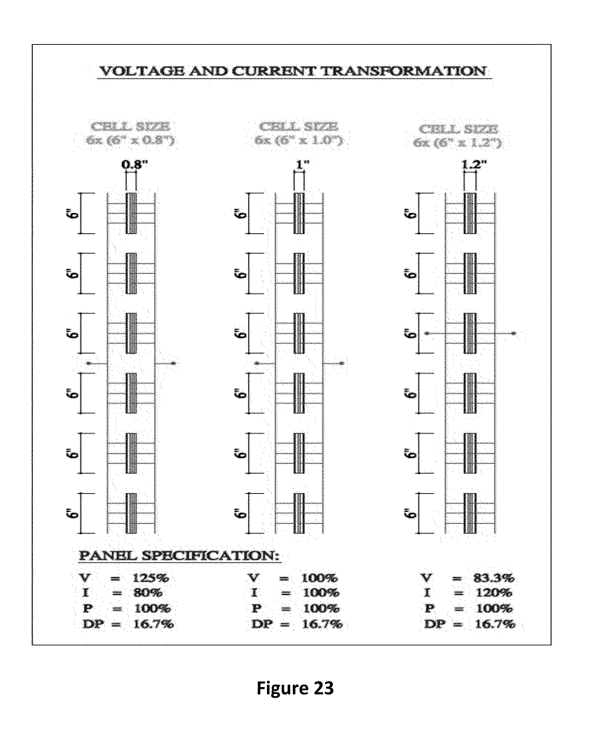

As an example of implementation of a dynamic PV module in accordance with an embodiment of the present invention, FIG. 23 illustrates a dynamic PV module having stacks of 6 cells each with adjusted dimensions for adjusting current and voltage to compensate for a decrease in the module voltage and/or decrease in the module current due to environmental factors in accordance with an embodiment of the present invention. The specifications of the PV module are as follow:

| | | | |
|---|---|---|---|
| Cell size | 6″ × 0.8″ | 6″ × 1.0″ | 6″ × 1.2″ |
| Voltage | 125% | 100% | 83.3% |
| Power | 100% | 100% | 100% |
| Current | 80% | 100% | 120% |
| Cell-to-Cell Dependency | 16.7% | 16.7% | 16.7% |

While the invention has been made described in details and with reference to specific embodiments thereof, it will be apparent to one skilled in the art that various additions, omissions, and modifications can be made without departing from the spirit and scope thereof.

1. A dynamic photovoltaic module having a module voltage and a module current, the photovoltaic module comprising a number of cell stacks connected in serial therebetween, each cell stack among said cell stacks comprising a number of photovoltaic cells connected in parallel therebetween, where each cell stack among said cell stacks has a cell stack voltage and a cell stack current and each photovoltaic cell among said photovoltaic cells has a cell voltage and a cell current such that the total voltage inside the module is equal to the module voltage and the total current inside the module is equal to the module current.

2. The dynamic photovoltaic module as claimed in claim 1 wherein each cell stack among said cell stacks comprises a same number of photovoltaic cells having a same cell voltage and cell current, the number of photovoltaic cells being equal to the quotient of the module current and the cell current and the number of cell stacks in the module being equal to the quotient of the module voltage and the cell voltage.

3. The photovoltaic module as claimed in claim 2 further comprising at least one bypass diode connected between the cell stacks in order to bypass the current around cell stacks experiencing a current mismatch effect.

4. The photovoltaic module as claimed in claim 3 wherein the at least one bypass diode is connected such that one bypass diode is connected in parallel between each two adjacent cell stacks or group of adjacent cell stacks.

5. The photovoltaic module as claimed in claim 4 further comprising at least one redundant bypass diode connected in parallel to the at least one bypass diode.

6. The photovoltaic module as claimed in claim 2, wherein each photovoltaic cell has a cell width and a cell length, and wherein the number of photovoltaic cells in a cell stack is equal to the quotient of the cell length and the cell width.

7. The photovoltaic module as claimed in claim 2 wherein the ratio of the cell length and the cell width is an integer number equal or above 2.

8. The photovoltaic module as claimed in claim 2 wherein the ratio of the cell length and the cell width is between 2 and 20.

9. The photovoltaic module as claimed in claim 2, where the module voltage and the module current are adjusted values taking into consideration the effect of environmental temperature and light radiance on the module.

10. The photovoltaic module as claimed in claim 2 further comprising bus-bars adapted to enable the parallel connection between the photovoltaic cells within a same cell stack.

11. The photovoltaic module as claimed in claim 2 further comprising string lines adapted to enable the serial connection between the different cell stacks.

12. A method of manufacturing a dynamic photovoltaic module having a module voltage and a module current adapted to reduce loss of energy caused by current mismatch inside the module, the method comprising forming a number of cell stacks connected in serial therebetween, each cell stack among said cell stacks comprising a number of photovoltaic cells connected in parallel therebetween, where each cell stack among said cell stacks has a cell stack voltage and a cell stack current and each photovoltaic cell among said photovoltaic cells has a cell voltage and a cell current such that the total voltage inside the module is equal to the module voltage and the total current inside the module is equal to the module current.

13. The method of claim 12 wherein each cell stack among said cell stacks comprises a same number of photovoltaic cells having a same cell voltage and cell current, the number of photovoltaic cells being equal to the quotient of the module current and the cell current and the number of cell stacks in the module being equal to the quotient of the module voltage and the cell voltage.

14. The method of claim 13 further comprising connecting at least one bypass diode between the cell stacks in order to bypass the current around cell stacks experiencing a mismatch effect.

15. The method of claim 14 wherein the at least one bypass diode is connected such that one bypass diode is connected in parallel between each two adjacent cell stacks or group of adjacent cell stacks.

16. The method of claim 15 further comprising at least one redundant bypass diode connected in parallel to the at least one bypass diode.

17. The method of claim 13 further comprising:
providing original PV cells having an original cell current, an original cell voltage, an original cell length and an original cell width; and
cutting the original PV cells for producing the PV cells used for forming the cell stacks, the PV cells having a cell length and a cell width.

18. The method of claim 17 wherein the original PV cells are cut using laser.

19. The method of claim 17 wherein the cell voltage is the same as the original cell voltage and wherein the cell current is equal to the quotient of the original cell current and the number of PV cells per stack.

20. The method of claim 19 wherein the cell length is the same as the original cell length and wherein the cell width is equal to the quotient of the original cell width and the number of PV cells per stack.

21. The method of claim 20 wherein the number of PV cells per stack is equal or above 2.

22. The method of claim 21 wherein the number of PV cells per stack is between 2 and 20.

23. The method of claim 22 wherein the number of PV cells is determined based on energy efficiency and cost considerations, where an increase in the number of PV cells per stack increases the cost of manufacturing the PV module from one side and increases from an other side the energy efficiency of the PV module by reducing the loss of energy caused by current mismatch inside the module.

24. The method of claim 13, wherein the module voltage and the module current are adjusted values taking into consideration the effect of environmental temperature and light radiance on the module.

25. The method of claim 13 wherein the parallel connection between the PV cells within each cell stack is conducted using bus-bars.

26. The method of claim 25 wherein the serial connection between the different cell stacks is conducted using string lines.

27. A dynamic PV system comprising at least two PV modules as claimed in claim 1 connected therebteween in parallel or serial.
